(19) United States
(12) Patent Application Publication
(10) Pub. No.: US 2011/0036393 A1
(43) Pub. Date: Feb. 17, 2011

(54) Thin-Film Solar Cell Module and a Manufacturing Method Thereof

(76) Inventors: Chia-Yu Chen, Taipei County (TW); Hui-Chu Lin, Hsinchu County (TW); Chien-Chung Bi, Taichung City (TW)

Correspondence Address: WPAT, PC;INTELLECTUAL PROPERTY ATTORNEYS, 2030 MAIN STREET, SUITE 1300, IRVINE, CA, 92614, US

(21) Appl. No.: 12/856,265

(22) Filed: Aug. 13, 2010

(30) Foreign Application Priority Data
Aug. 14, 2009 (TW) 098127443

(51) Int. Cl. H01L 31/0288; H01L 31/00; H01L 31/0376; H01L 31/036; H01L 31/18

(52) U.S. Cl. 136/255; 136/252; 136/258; 438/93; 438/96; 257/E31.047; 257/E31.04

(57) ABSTRACT

The present invention discloses a thin film solar cell module and a manufacturing method thereof. The thin film solar cell comprises, from bottom to top, a first substrate, a first electrode, an absorber layer, and a second electrode layer. A first current output region formed at the positive electrode of the thin film solar cell module. A first current output element is disposed in the first current output region, and the absorber layer further comprises at least a first gap which is disposed in the first current output region to increase the contact between the first electrode layer and the second electrode layer. The useless current, the resistance and the heat generated there are reduced. The heat generated there is also reduced.

### BACKGROUND OF THE INVENTION

1. Field of the Invention

The present invention relates to a solar cell, more particularly relating to a thin-film solar cell and the manufacturing method thereof that can reduce the heat generated by the useless current of the positive electrode and the reverse current of the negative electrode.

2. Description of the Prior Art

A solar cell is a photovoltaic semiconductor device that directly converts the energy of the sunlight into electricity and outputs a current with a voltage by the photoelectric effect. Therefore, a solar cell is also called as a photovoltaic (PV) cell. A solar cell can be classified as a silicon-based solar cell, a thin film solar cell, a dye-sensitized solar cell, or an organic/polymer solar cell, according to the categories of the light-absorbing material used in the solar cell.

A solar cell mainly comprises a substrate, a front electrode layer, an absorber layer and a back electrode layer. The absorber layer can uptake incident light to generate electron-hole pairs by photovoltaic effect. Electrons and holes move toward opposing directions respectively by the intrinsic electric field built in the absorber layer. A voltage difference is therefore generated between the positive electrode and the negative electrode of the solar cell. To output a current generated between the two electrodes of the solar cell, a solder bump is disposed on each of the two electrodes. The current is therefore output from the two electrode layers via the electrical connection provided by the solder bump.

The current generated by the positive electrode of the solar cell at the solder bump cannot be output via the solder bump. Therefore, the current generated there is a useless current for it cannot be utilized effectively. If the absorber there continuously generates current via photovoltaic effect, accumulation of the useless current is therefore resulted in the heat generation there and the elevation of temperature. In addition, a reverse current will be caused by the electrically serial- or parallel-contact of the positive electrode and other general electronics. The reverse current, when encounters the absorber layer that functions as a electrical resistance to it, will generate heat and temperature there will be elevated. Therefore, a conventional solar cell usually has the problem of temperature being elevated at the solder bump. If the temperature there is elevated above a threshold, the normal function of the elements of a solar cell will be effected, or even out of function. On the other hand, at the negative electrode of a conventional solar cell, the front electrode layer electrically contacts to the second electrode layer via only the solder bump there, which results a small contact area between the two electrode layers and limits the amount of the conducted electricity.

### SUMMARY OF THE INVENTION

In order to overcome the shortcomings of high temperature resulted from the heat generated at the positive electrode of a solar cell, as well as the limited electricity resulted from the small contact of the front and back electrode layers at the negative electrode mentioned previously, the present invention provides a thin film solar cell module. The thin film solar cell module comprises a gap disposed in the absorber layer at the positive electrode or the negative electrode. The gap increase the contact between the front and the back electrode layers to reduce the useless current and resistance generated at the positive electrode. The heat generated there is therefore reduced to prevent the elevation of the temperature.

The primary object of the present invention is to provide a thin film solar cell module. The thin film solar cell module comprises a substrate, a first electrode layer formed on the substrate, an absorber layer formed on the first electrode layer, and a second electrode layer formed on the absorber layer. A first current output region formed at the positive electrode of the thin film solar cell module. A first current output element is disposed in the first current output region, and the absorber layer further comprises at least a first gap which is disposed in the first current output region to increase the contact between the first electrode layer and the second electrode layer. Therefore, the useless current and resistance are reduced. The heat generated there is also reduced.

In addition, the thin film solar cell module further comprises a second current output region formed at the negative electrode. A second current output element is disposed in the second current output region. The absorber layer comprises at least a second gap which is disposed in the second current output region to further increase the contact area between the first electrode layer and the second electrode layer.

Another object of the present invention is to provide a manufacturing method of a thin film solar cell module, comprising the following steps. (1) Providing a substrate. (2) Forming a first electrode layer on the substrate. (3) Forming an absorber layer on the first electrode layer. (4) Forming a first current output region at a positive electrode of the thin film solar cell module, and forming a first gap on the absorber layer at the first current output region. (5) Forming a second electrode layer on the absorber layer. (6) Disposing a first current output element at the first current output region. The first gap is capable of increasing the contact between the first electrode layer and the second electrode layer at the first current output region.

In addition, the step (4) may further comprise forming a second current output region at a negative electrode of the thin film solar cell module and disposing a second gap in the absorber layer at the second current output region to further increase the contact between the first electrode layer and the second electrode layer. Moreover, the step (6) may further comprise disposing a second current output element in the second current output region.

In the thin film solar cell module and the manufacturing method thereof mentioned previously, either the first gap or the second gap may be formed by laser scribing, and either the first or the second current output element may be a soldering tin. In addition, the material of the substrate may be soda-lime glass, low iron glass, or alkali-free glass. The material of the absorber layer may be amorphous silicon, polymorphous silicon, microcrystalline silicon (mc-Si) and microcrystalline silicon germanium (mc-SiGe). The material of the first electrode layer may be a transparent conductive oxide. The material of the second electrode layer may be a transparent conductive oxide (TCO), a metal and a metal-transparent-conductive-oxide complex. The transparent conductive oxide may be indium doped tin oxide (ITO), indium doped zinc oxide (IZO), aluminum doped zinc oxide (AZO), boron doped zinc oxide (BZO), gallium doped zinc oxide (GZO), or zinc oxide (ZnO). And the metal may be aluminum (Al), nickel (Ni), gold (Au), silver (Ag), chromium (Cr), titanium (Ti), or palladium (Pd).

The thin film solar cell module and the manufacturing method thereof can increase the contact area between the first electrode layer and the second electrode layer at the positive or the negative electrode. For a portion of the absorber layer in the first current output region at the positive electrode is removed owing to the disposition of the first gap, the current (the useless current) that is generated in the first current output region and cannot be output is reduced. The heat resulted from the useless current is also reduced. The resistance is therefore reduced to prevent the generation of the heat resulted from the reverse current and the resistance. Therefore, the thin film solar cell module and the manufacturing method thereof provided by the present invention can efficiently reduce the generation of the heat at the positive electrode, which achieves the object to reduce the temperature of the positive electrode and can prevent the defects of the elements of the solar cell resulted from the high temperature.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A is a cross-sectional view of the thin film solar cell module according to the first preferred embodiment of the present invention (the arrowhead represents the incident light.);

FIG. 1B is a cross-sectional view of the thin film solar cell module according to the second preferred embodiment of the present invention (the arrowhead represents the incident light.); and

FIG. 2 is a flow chart of the manufacturing method of the thin film solar cell module for manufacturing the above first and/or second preferred embodiments of the present invention.

FIG. 3 is a flow chart of another manufacturing method of the thin film solar cell module for manufacturing the above first and/or second preferred embodiments of the present invention.

### DESCRIPTION OF THE PREFERRED EMBODIMENT

A detailed description of the present invention will be given below with reference to preferred embodiments thereof, so that a person skilled in the art can readily understand features and functions of the present invention after reviewing the contents disclosed herein. The present invention can also be implemented by or applied in other embodiments, where changes and modifications can be made to the disclosed details from a viewpoint different from that adopted in this specification without departing from the spirit of the present invention.

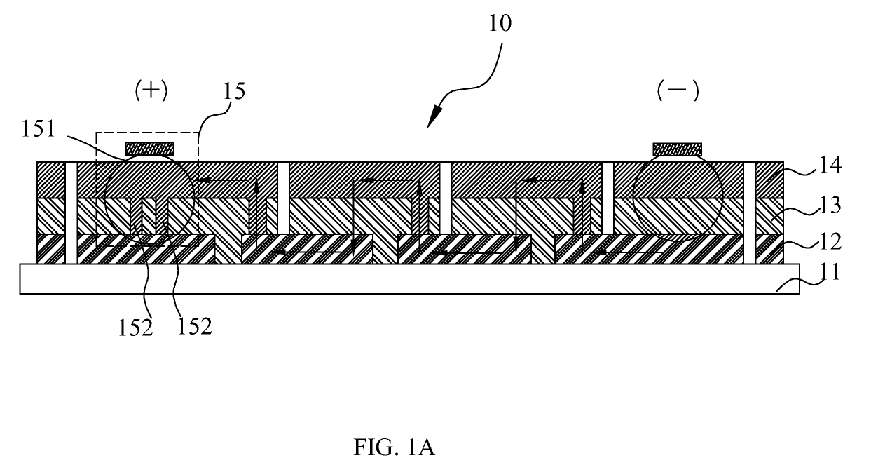

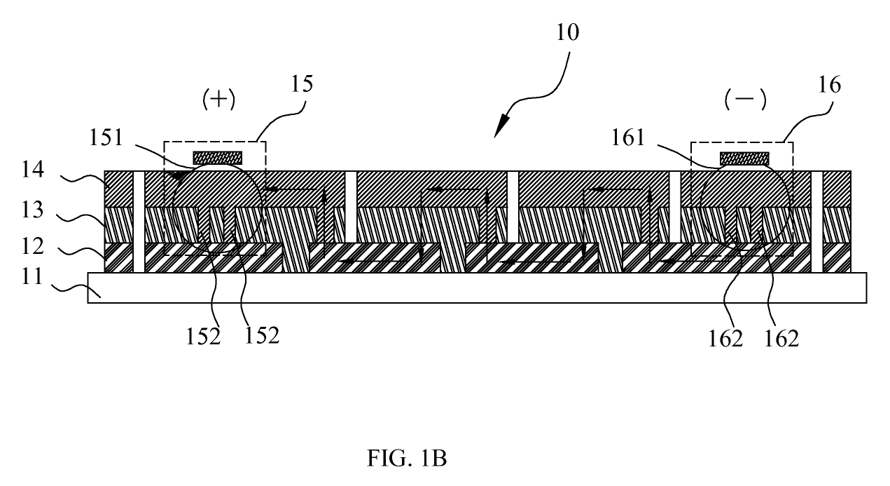

Please refer to FIG. 1A, which is a cross-sectional view of the thin film solar cell module according to the first preferred embodiment of the present invention. The arrowhead represents the incident light. The thin film solar cell module 10 comprises a substrate 11, a first electrode layer 12 formed on the substrate 11, an absorber layer 13 formed on the first electrode layer 12, a second electrode layer 14 formed on the absorber layer 13, and a first current output region 15 formed at the positive electrode of the thin film solar cell module 10. A first current output element 151 is disposed in the first current output region, and the absorber layer 13 further comprises at least a first gap 152 which is disposed in the first current output region 15 to increase the contact area between the first electrode layer 12 and the second electrode layer 14. In addition, for a portion of the absorber layer 13 in the first current output region at the positive electrode is removed owing to the disposition of the first gap 152 (that is, the area of the absorber layer 13 is reduced), the current that is generated there by the photovoltaic effect is relatively reduced. The resistance is also reduced. The useless current generated in the first current output region 151 is therefore reduced. The heat resulted from the useless current is also reduced. The amount of the heat resulted from the reverse current and the resistance is decreased. Therefore, the generation of the heat at the positive electrode of the thin film solar cell module 10 is reduced, which achieve the object to reduce the temperature of the positive electrode and can prevent the defects of the elements of the thin film solar cell module 10 resulted from the high temperature.

In addition, the present invention provides another thin film solar cell module according to the second preferred embodiment. The second preferred embodiment of the present invention is substantially the same as the first embodiment except the elements described as following. Please refer to FIG. 1B. The thin film solar cell module 10 may further comprise a second current output region 16 formed at the negative electrode of the thin film solar cell module 10. A second current output element 161 is disposed in the second current output region 16, and the absorber layer 13 may further comprise at least a second gap 162 which is disposed in the second current output region 16 to make the first electrode layer 12 contact directly there with the second electrode layer 14 and further increase the contact area between the first electrode layer 12 and the second electrode layer 14, which results in the elevation of the amount of the conducted electricity.

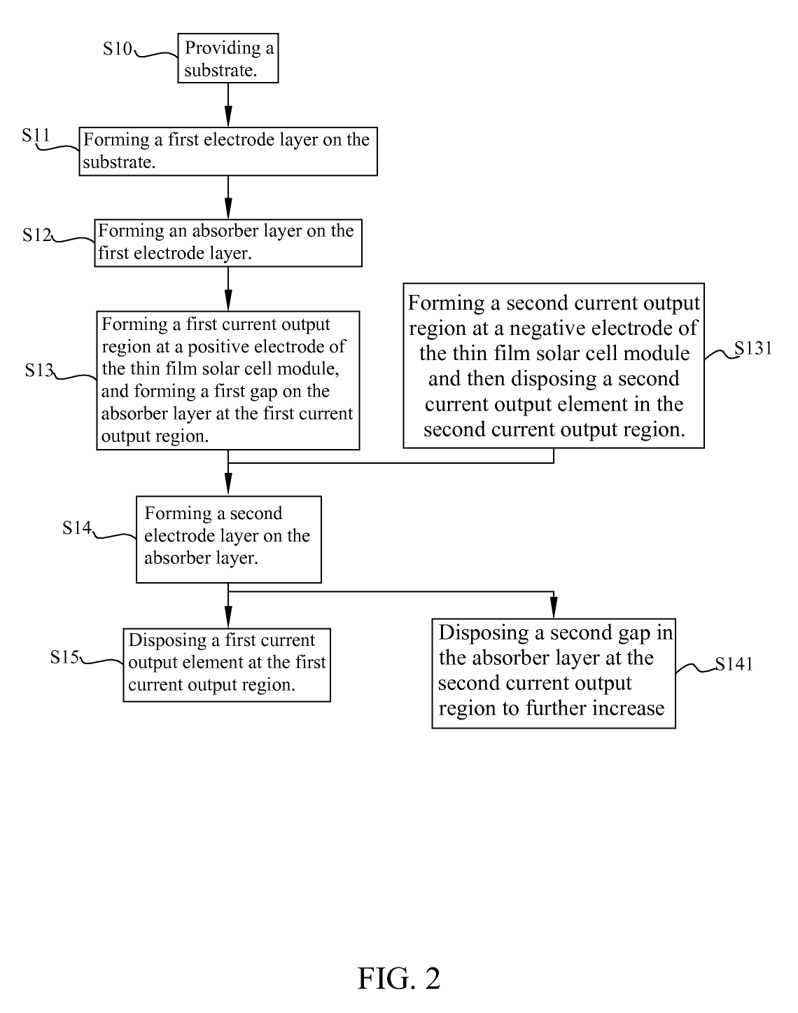

Please refer to FIG. 2, which is a flow chart of the manufacturing method of the thin film solar cell module for manufacturing the above first and/or second preferred embodiments of the present invention.

The manufacturing method of a thin film solar cell module comprises the following steps.

Step S10: Providing a substrate.

Step S11: Forming a first electrode layer on the substrate.

Step S12: Forming an absorber layer on the first electrode layer.

Step S13: Forming a first current output region at a positive electrode of the thin film solar cell module, and forming a first gap on the absorber layer at the first current output region.

Step S14: Forming a second electrode layer on the absorber layer.

Step S15: Disposing a first current output element at the first current output region.

The disposing of the first gap is capable of increasing the contact area between the first electrode layer and the second electrode layer at the first current output region and reducing the resistance and the generation of the useless current. Both the heat resulted from the useless current and from the reverse current and the resistance is also reduced, which achieves the object to reduce the temperature of the positive electrode and can prevent the defects of the elements of the solar cell resulted from the high temperature.

In addition, the manufacturing method of a solar cell may further comprises a step S131 of forming a second current output region at a negative electrode of the thin film solar cell module and then disposing a second current output element in the second current output region, and a step S141 of disposing a second gap in the absorber layer at the second current output region to further increase the contact between the first electrode layer and the second electrode layer. The disposing of the second gap may result in the direct contact of the first electrode lay and the second electrode layer at the second current output region. The contact area between the first electrode layer and the second electrode layer is therefore increased to elevate of the amount of the conducted electricity.

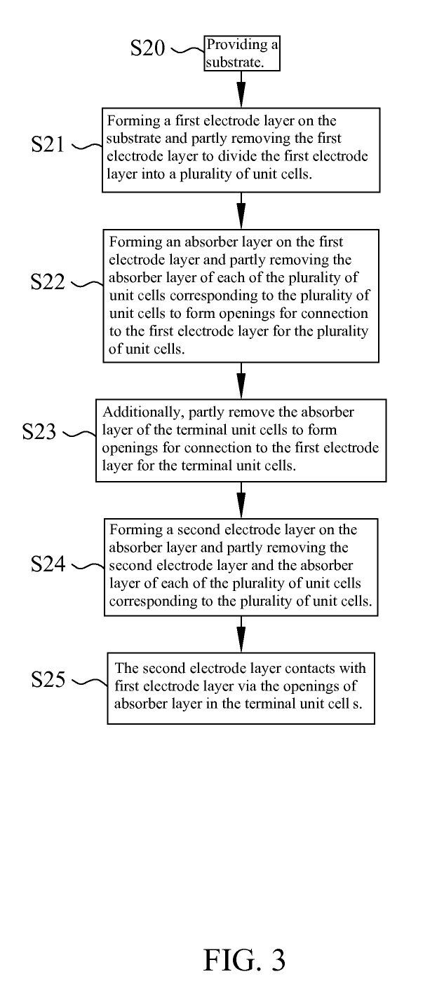

Please further refer to FIG. 3, which shows another flow chart of the manufacturing method of the thin film solar cell module for manufacturing the above first and/or second preferred embodiments of the present invention. The manufacturing method of a thin film solar cell module comprises the following steps.

Step S20: Providing a substrate.

Step S21: Forming a first electrode layer on the substrate and partly removing the first electrode layer to divide the first electrode layer into a plurality of unit cells.

Step S22: Forming an absorber layer on the first electrode layer and partly removing the absorber layer of each of the plurality of unit cells corresponding to the plurality of units to form openings for connection to the first electrode layer for the plurality of unit cells.

Step S23: Partly remove the absorber layer of the terminal unit cells to form openings for connection to the first electrode layer for the terminal unite cells

Step 24: Forming a second electrode layer on the absorber layer and partly removing the second electrode layer and the absorber layer of each of the plurality of unit cells corresponding the the plurality of unit cells.

Step S25: The second electrode layer contacts with the first electrode layer via the openings of the absorber layer in the terminal unite cells.

The disposing of the first gap is capable of increasing the contact area between the first electrode layer and the second electrode layer at the first current output region and reducing the resistance and the generation of the useless current. Both the heat resulted from the useless current and from the reverse current and the resistance is also reduced, which achieves the object to reduce the temperature of the positive electrode and can prevent the defects of the elements of the solar cell resulted from the high temperature.

In the thin film solar cell module 10 and the manufacturing method of the thin film solar cell module mentioned above, either the first gap 152 or the second gap 162 is, but not limited to, formed by laser scribing. Any method that can form the gap in the absorber layer 13 at either the first current output region 15 or the second current output region 16 is applicable to this invention, and such gap formed by the method is capable of increasing the contact area between the first electrode layer 12 and the second electrode layer 14. Such method, for example, is an optical scribing or mechanical scribing process. Moreover, either the first current output element 151 or the second current output element 161 is, but not limited to, a soldering tin. Other materials that can electrically conduct a current are also applicable in this invention.

In addition, in the thin film solar cell module mentioned previously, the material of the substrate 11 may be soda-lime glass, low iron glass, or alkali-free glass. The material of the absorber layer 13 may be amorphous silicon, polymorphous silicon, microcrystalline silicon (mc-Si) and microcrystalline silicon germanium (mc-SiGe). The material of the first electrode layer 12 may be a transparent conductive oxide. The material of the second electrode layer 14 may be a transparent conductive oxide (TCO), a metal and a metal-transparent-conductive-oxide complex. The transparent conductive oxide may be indium doped tin oxide (ITO), indium doped zinc oxide (IZO), aluminum doped zinc oxide (AZO), boron doped zinc oxide (BZO), gallium doped zinc oxide (GZO), or zinc oxide (ZnO). And the metal may be aluminum (Al), nickel (Ni), gold (Au), silver (Ag), chromium (Cr), titanium (Ti), or palladium (Pd).

The present invention can also be implemented by or applied in other embodiments, where changes and modifications can be made to the disclosed details from a viewpoint different from that adopted in this specification without departing from the spirit of the present invention.

What is claimed is:

1. A thin film solar cell module, comprising:
a substrate;
a first electrode layer, formed on the substrate;
an absorber layer, formed on the first electrode layer wherein a gap is formed in one edge of the solar cell module by laser scribing;
a second electrode layer, formed on the absorber layer so that the first electrode layer is partly and electrically connected to the second electrode layer; and
a current output region formed at an electrode of the thin film solar cell module.

2. The thin film solar cell module of claim 1, wherein the electrode is a positive electrode.

3. The thin film solar cell module of claim 1, wherein the electrode is a negative electrode.

4. The thin film solar cell module of claim 1, the first current output element is a soldering tin.

5. The thin film solar cell module of claim 1, wherein the substrate is made of a material selected from the group consisting of soda-lime glass, low iron glass, and alkali-free glass.

6. The thin film solar cell module of claim 1, wherein the absorber layer is made of a material selected from the group consisting of amorphous silicon, polymorphous silicon, microcrystalline silicon (mc-Si) and microcrystalline silicon germanium (mc-SiGe).

7. The thin film solar cell module of claim 1, wherein the first electrode layer is made of a transparent conductive oxide (TCO), and the transparent conductive oxide is selected from the group consisting of indium doped tin oxide (ITO), indium doped zinc oxide (IZO), aluminum doped zinc oxide (AZO), boron doped zinc oxide (BZO), gallium doped zinc oxide (GZO), and zinc oxide (ZnO).

8. The thin film solar cell module of claim 1, wherein the second electrode layer is made of a material selected from the group consisting of a transparent conductive oxide (TCO), a metal and a metal-transparent-conductive-oxide complex.

9. The thin film solar cell module of claim 8, wherein the transparent conductive oxide is selected from the group consisting of indium doped tin oxide (ITO), indium doped zinc oxide (IZO), aluminum doped zinc oxide (AZO), boron doped zinc oxide (BZO), gallium doped zinc oxide (GZO), and zinc oxide (ZnO).

10. The thin film solar cell module of claim 1, wherein the metal is selected from the group consisting of aluminum (Al), nickel (Ni), gold (Au), silver (Ag), chromium (Cr), titanium (Ti), and palladium (Pd).

11. A manufacturing method of a thin film solar cell module, comprising the steps of:
(1) providing a substrate;
(2) forming a first electrode layer on the substrate;
(3) forming an absorber layer on the first electrode layer wherein a gap is positioned in one edge of the solar cell module by laser scribing;
(4) forming a second electrode layer on the absorber layer so that the first electrode layer is partly and electrically connected to the second electrode layer; and
(5) disposing a current output element at the current output region.

12. The manufacturing method of a thin film solar cell module of claim 11, wherein the current output element is the positive electrode.

13. The manufacturing method of a thin film solar cell module of claim 11, the first current output element is a soldering tin.

14. The manufacturing method of a thin film solar cell module of claim 11, wherein the step (4) further comprises forming a second current output region at a negative electrode of the thin film solar cell module and disposing a second gap in the absorber layer at the second current output region to further increase the contact between the first electrode layer and the second electrode layer.

15. The manufacturing method of a thin film solar cell module of claim 11, wherein the substrate is made of a material selected from the group consisting of soda-lime glass, low iron glass, and alkali-free glass.

16. The manufacturing method of a thin film solar cell module of claim 11, wherein the absorber layer is made of a material selected from the group consisting of amorphous silicon, polymorphous silicon, microcrystalline silicon (mc-Si) and microcrystalline silicon germanium (mc-SiGe).

17. The manufacturing method of a thin film solar cell module of claim 11, wherein the first electrode layer is made of a transparent conductive oxide (TCO), and the transparent conductive oxide is selected from the group consisting of indium doped tin oxide (ITO), indium doped zinc oxide (IZO), aluminum doped zinc oxide (AZO), boron doped zinc oxide (BZO), gallium doped zinc oxide (GZO), and zinc oxide (ZnO).

18. The manufacturing method of a thin film solar cell module of claim 11, wherein the second electrode layer is made of a material selected from the group consisting of a transparent conductive oxide (TCO), a metal and a metal-transparent-conductive-oxide complex.

19. The manufacturing method of a thin film solar cell module of claim 18, wherein the transparent conductive oxide is selected from the group consisting of indium doped tin oxide (ITO), indium doped zinc oxide (IZO), aluminum doped zinc oxide (AZO), boron doped zinc oxide (BZO), gallium doped zinc oxide (GZO), and zinc oxide (ZnO).

20. The manufacturing method of a thin film solar cell module of claim 18, wherein the metal is selected from the group consisting of aluminum (Al), nickel (Ni), gold (Au), silver (Ag), chromium (Cr), titanium (Ti), and palladium (Pd).
